(19) United States
(12) Patent Application Publication
(10) Pub. No.: US 2024/0381676 A1
(43) Pub. Date: Nov. 14, 2024

(54) DETECTION DEVICE

(71) Applicant: Japan Display Inc., Tokyo (JP)

(72) Inventor: Gen KOIDE, Tokyo (JP)

(21) Appl. No.: 18/782,316

(22) Filed: Jul. 24, 2024

Related U.S. Application Data
(63) Continuation of application No. PCT/JP2023/001149, filed on Jan. 17, 2023.

(30) Foreign Application Priority Data
Feb. 1, 2022 (JP) 2022-014144

(51) Int. Cl. H10K 39/32; G06V 40/13; G06V 40/145

(52) U.S. Cl. CPC H10K 39/32; G06V 40/1318; G06V 40/145

(57) ABSTRACT

According to an aspect, a detection device includes a substrate and a plurality of photodiodes arranged on the substrate. Each of the photodiodes includes a lower electrode, a lower buffer layer, an active layer, an upper buffer layer, and an upper electrode that are stacked on the substrate in the order as listed. A plurality of the lower electrodes are each provided with a plurality of openings.

### CROSS-REFERENCE TO RELATED APPLICATION

This application claims the benefit of priority from Japanese Patent Application No. 2022-014144 filed on Feb. 1, 2022 and International Patent Application No. PCT/JP2023/001149 filed on Jan. 17, 2023, the entire contents of which are incorporated herein by reference.

### BACKGROUND

### 1. Technical Field

What is disclosed herein relates to a detection device.

### 2. Description of the Related Art

Optical sensors capable of detecting fingerprint patterns and vein patterns are known (refer to, for example, Japanese Patent Application Laid-open Publication No. 2009-032005). Among such optical sensors, sensors are known each including a plurality of photodiodes in which an organic semiconductor material is used as an active layer. The organic semiconductor material is disposed between a lower electrode and an upper electrode.

Although increasing the area of the lower electrode of each of the photodiodes can increase the capacitance of the sensor, the time required to read photocarriers (electrons or holes) generated by irradiation of light may increase. On the other hand, reducing the area of the lower electrode of each of the photodiodes may reduce the sensitivity of the sensor.

For the foregoing reasons, there is a need for a detection device capable of improving the detection performance.

### SUMMARY

According to an aspect, a detection device includes a substrate and a plurality of photodiodes arranged on the substrate. Each of the photodiodes includes a lower electrode, a lower buffer layer, an active layer, an upper buffer layer, and an upper electrode that are stacked on the substrate in the order as listed. A plurality of the lower electrodes are each provided with a plurality of openings.

### BRIEF DESCRIPTION OF THE DRAWINGS

FIG. 1 is a plan view schematically illustrating a detection device according to an embodiment of the present disclosure;

FIG. 2 is a block diagram illustrating a configuration example of the detection device according to the embodiment;

FIG. 3 is a circuit diagram illustrating the detection device;

FIG. 4 is a circuit diagram illustrating a plurality of partial detection areas;

FIG. 5 is a plan view illustrating a lower electrode of the detection device according to the embodiment in an enlarged manner;

FIG. 6 is a sectional view along VI-VI′ of FIG. 5;

FIG. 7 is an explanatory diagram for explaining an operation example of the detection device;

FIG. 8 illustrates explanatory diagrams each for explaining a potential of a lower buffer layer in areas overlapping an electrode portion and an opening of the lower electrode;

FIG. 9 is a plan view illustrating a lower electrode of a detection device according to a first modification in an enlarged manner; and

FIG. 10 is a plan view illustrating a lower electrode of a detection device according to a second modification in an enlarged manner.

### DETAILED DESCRIPTION

The following describes a mode (embodiment) for carrying out the present disclosure in detail with reference to the drawings. The present disclosure is not limited to the description of the embodiment given below. Components described below include those easily conceivable by those skilled in the art or those substantially identical thereto. In addition, the components described below can be combined as appropriate. What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate.

In the present specification and claims, in expressing an aspect of disposing another structure on or above a certain structure, a case of simply expressing “on” includes both a case of disposing the other structure immediately on the certain structure so as to contact the certain structure and a case of disposing the other structure above the certain structure with still another structure interposed therebetween, unless otherwise specified.

### Embodiment

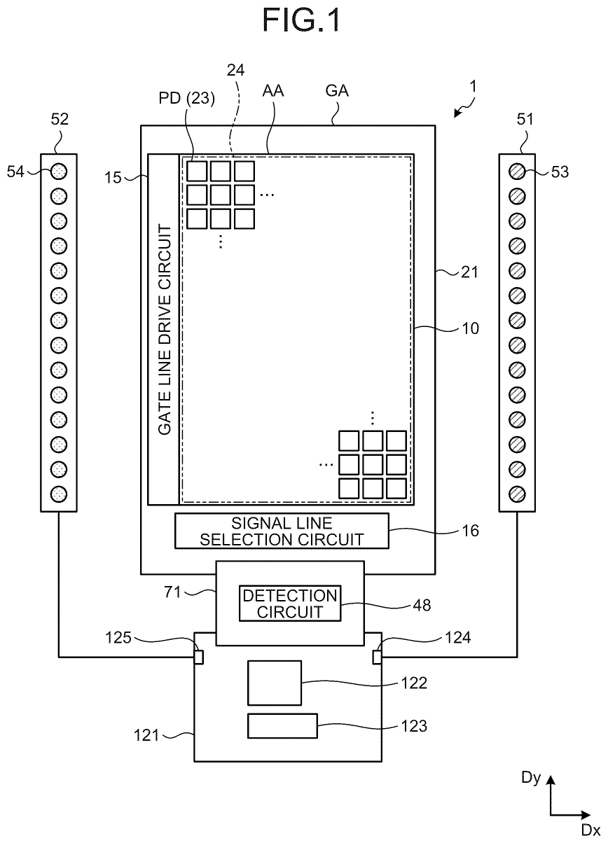

FIG. 1 is a plan view schematically illustrating a detection device according to an embodiment of the present disclosure. As illustrated in FIG. 1, a detection device 1 includes a substrate 21, a sensor 10, a gate line drive circuit 15, a signal line selection circuit 16, a detection circuit 48, a control circuit 122, a power supply circuit 123, a first light source base member 51, a second light source base member 52, and light sources 53 and 54. The first light source base member 51 is provided with a plurality of the light sources 53. The second light source base member 52 is provided with a plurality of the light sources 54.

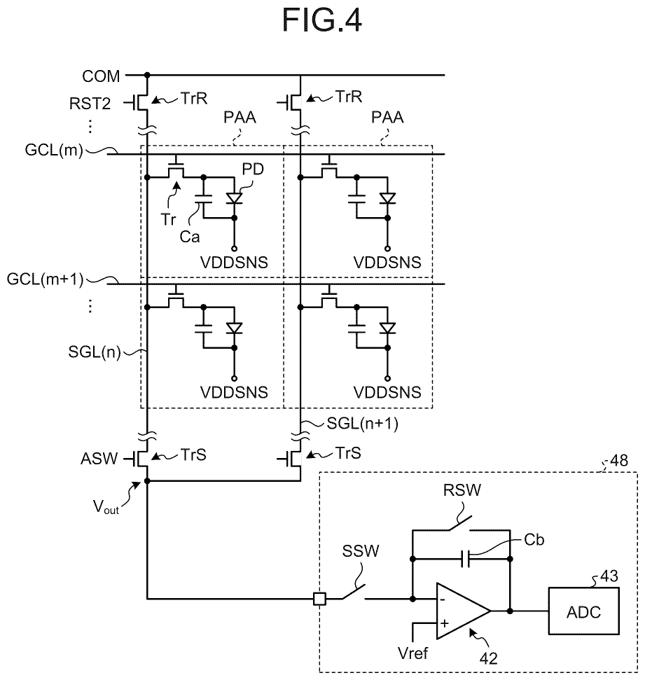

The substrate 21 is electrically coupled to a control substrate 121 through a wiring substrate 71. The wiring substrate 71 is, for example, a flexible printed circuit board or a rigid circuit board. The wiring substrate 71 is provided with the detection circuit 48. The control substrate 121 is provided with the control circuit 122 and the power supply circuit 123. The control circuit 122 is a field-programmable gate array (FPGA), for example. The control circuit 122 supplies control signals to the sensor 10, the gate line drive circuit 15, and the signal line selection circuit 16 to control detection operations of the sensor 10. The control circuit 122 supplies control signals to the light sources 53 and 54 to control lighting and non-lighting of the light sources 53 and 54. The power supply circuit 123 supplies voltage signals including, for example, a sensor power supply signal (sensor power supply voltage) VDDSNS (refer to FIG. 4) to the sensor 10, the gate line drive circuit 15, and the signal line selection circuit 16. The power supply circuit 123 supplies a power supply voltage to the light sources 53 and 54.

The substrate 21 has a detection area AA and a peripheral area GA. The detection area AA is an area provided with a plurality of photodiodes PD included in the sensor 10. The peripheral area GA is an area between the outer perimeter of the detection area AA and the ends of the substrate 21, and is an area not provided with the photodiodes PD.

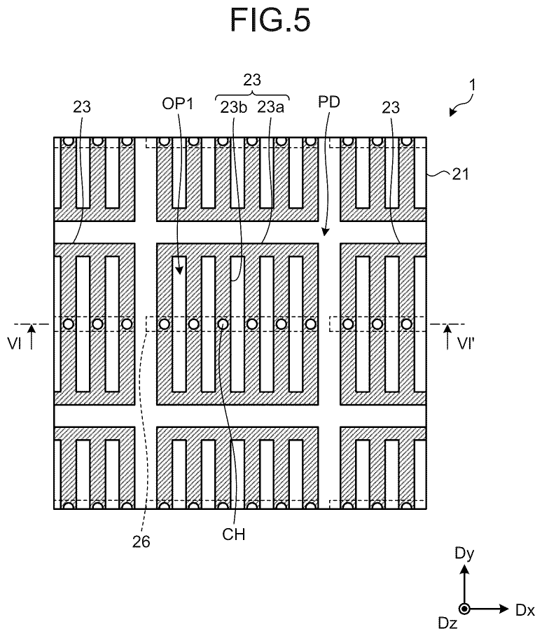

The sensor 10 includes the photodiodes PD as optical sensor elements. Each of the photodiodes PD outputs an electrical signal corresponding to light emitted thereto. More specifically, the photodiode PD is an organic photodiode (OPD) using an organic semiconductor. The photodiodes PD are arranged in a matrix having a row-column configuration in the detection area AA. The photodiode PD includes a lower electrode 23 disposed on the lower side of the organic semiconductor and an upper electrode 24 disposed on the upper side of the organic semiconductor. A plurality of the lower electrodes 23 are provided one for each of the photodiodes PD and are arranged in a matrix having a row-column configuration in the detection area AA. The upper electrode 24 is provided across the photodiodes PD and provided continuously in the detection area AA. The configuration of the photodiodes PD, the lower electrodes 23, and the upper electrode 24 will be described later with reference to FIG. 5 and the subsequent drawings.

Each of the photodiodes PD performs detection in response to a gate drive signal VGL supplied from the gate line drive circuit 15. Each of the photodiodes PD outputs the electrical signal corresponding to the light emitted thereto as a detection signal Vdet to the signal line selection circuit 16. The detection device 1 detects information on an object to be detected, based on the detection signals Vdet received from the photodiodes PD.

The gate line drive circuit 15 and the signal line selection circuit 16 are provided in the peripheral area GA. Specifically, the gate line drive circuit 15 is provided in an area extending along a second direction Dy in the peripheral area GA. The signal line selection circuit 16 is provided in an area extending along a first direction Dx in the peripheral area GA, and is provided between the sensor 10 and the detection circuit 48.

In the following description, the first direction Dx is a direction in a plane parallel to the substrate 21. The second direction Dy is a direction in the plane parallel to the substrate 21, and is a direction orthogonal to the first direction Dx. The second direction Dy may non-orthogonally intersect the first direction Dx. The term “plan view” refers to a positional relation when viewed in a direction orthogonal to the substrate 21.

The light sources 53 are provided on the first light source base member 51 and arranged along the second direction Dy. The light sources 54 are provided on the second light source base member 52 and arranged along the second direction Dy. The first light source base member 51 and the second light source base member 52 are electrically coupled, through respective terminals 124 and 125 provided on the control substrate 121, to the control circuit 122 and the power supply circuit 123.

For example, inorganic light-emitting diodes (LEDs) or organic electroluminescent (EL) diodes (organic light-emitting diodes (OLEDs)) are used as the light sources 53 and 54. The light sources 53 and 54 emit light having different wavelengths from each other.

First light emitted from the light sources 53 is mainly reflected on a surface of the object to be detected, such as a finger, and enters the sensor 10. As a result, the sensor 10 can detect a fingerprint by detecting a shape of asperities on the surface of the finger or the like. Second light emitted from the light sources 54 is mainly reflected in the finger or the like, or transmitted through the finger or the like, and enters the sensor 10. As a result, the sensor 10 can detect information on a living body in the finger or the like. Examples of the information on the living body include pulse waves, pulsation, and a vascular image of the finger or a palm. That is, the detection device 1 may be configured as a fingerprint detection device to detect a fingerprint or a vein detection device to detect a vascular pattern of, for example, veins.

The arrangement of the light sources 53 and 54 illustrated in FIG. 1 is merely an example, and can be changed as appropriate. The detection device 1 is provided with a plurality of types of the light sources 53 and 54 as light sources. However, the light sources are not limited thereto, and may be of one type. For example, the light sources 53 and 54 may be arranged on each of the first and the second light source base members 51 and 52. The light sources 53 and 54 may be provided on one light source base member, or three or more light source base members. Alternatively, only at least one light source needs to be disposed.

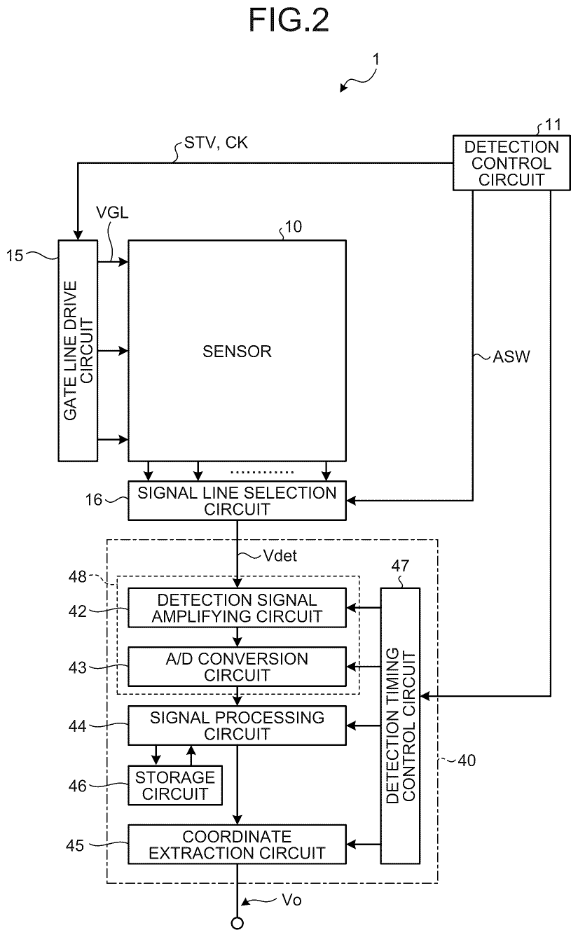

FIG. 2 is a block diagram illustrating a configuration example of the detection device according to the embodiment. As illustrated in FIG. 2, the detection device 1 further includes a detection control circuit 11 and a detector (detection signal processing circuit) 40. The control circuit 122 includes one, some, or all functions of the detection control circuit 11. The control circuit 122 also includes one, some, or all functions of the detector 40 other than those of the detection circuit 48.

The detection control circuit 11 is a circuit that supplies respective control signals to the gate line drive circuit 15, the signal line selection circuit 16, and the detector 40 to control operations of these components. The detection control circuit 11 supplies various control signals including, for example, a start signal STV and a clock signal CK to the gate line drive circuit 15. The detection control circuit 11 also supplies various control signals including, for example, a selection signal ASW to the signal line selection circuit 16. The detection control circuit 11 also supplies various control signals to the light sources 53 and 54 to control the lighting and non-lighting of the respective light sources 53 and 54.

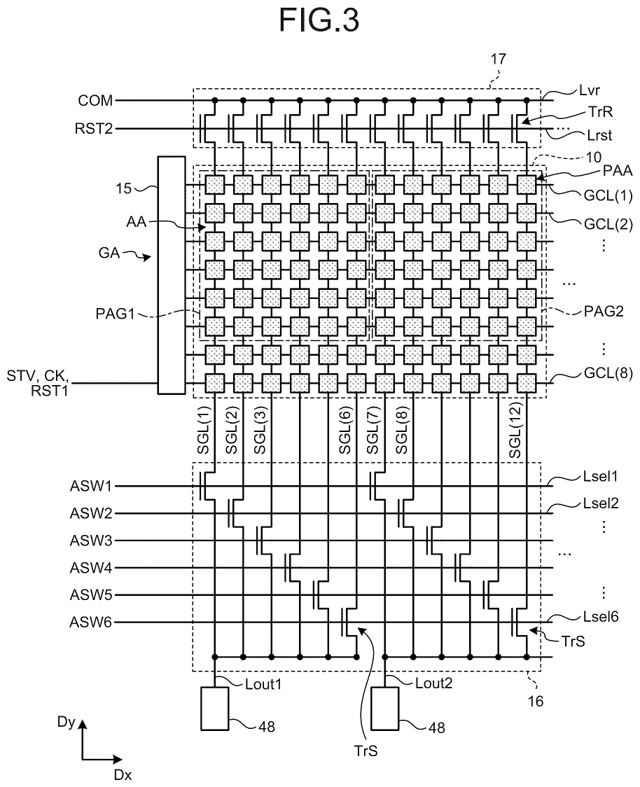

The gate line drive circuit 15 is a circuit that drives a plurality of gate lines GCL (refer to FIG. 3) based on the various control signals. The gate line drive circuit 15 sequentially or simultaneously selects the gate lines GCL and supplies the gate drive signals VGL to the selected gate lines GCL. By this operation, the gate line drive circuit 15 selects the photodiodes PD coupled to the gate lines GCL.

The signal line selection circuit 16 is a switch circuit that sequentially or simultaneously selects a plurality of signal lines SGL (refer to FIG. 3). The signal line selection circuit 16 is a multiplexer, for example. The signal line selection circuit 16 couples the selected signal lines SGL to the detection circuit 48 based on the selection signal ASW supplied from the detection control circuit 11. Through this operation, the signal line selection circuit 16 outputs the detection signal Vdet of the photodiode PD to the detector 40.

The detector 40 includes the detection circuit 48, a signal processing circuit 44, a coordinate extraction circuit 45, a storage circuit 46, and a detection timing control circuit 47. The detection timing control circuit 47 controls the detection circuit 48, the signal processing circuit 44, and the coordinate extraction circuit 45 so as to operate in synchronization with one another based on a control signal supplied from the detection control circuit 11.

The detection circuit 48 is an analog front-end (AFE) circuit, for example. The detection circuit 48 is a signal processing circuit having functions of at least a detection signal amplifying circuit 42 and an analog-to-digital (A/D) conversion circuit 43. The detection signal amplifying circuit 42 amplifies the detection signal Vdet. The A/D conversion circuit 43 converts analog signals output from the detection signal amplifying circuit 42 into digital signals.

The signal processing circuit 44 is a logic circuit that detects predetermined physical quantities received by the sensor 10 based on the output signals of the detection circuit 48. The signal processing circuit 44 can detect the asperities on the surface of the finger or the palm based on the signals from the detection circuit 48 when the finger is in contact with or in proximity to a detection surface. The signal processing circuit 44 can detect the information on the living body based on the signals from the detection circuit 48. Examples of the information on the living body include the vascular image, the pulse waves, the pulsation, and a blood oxygen level of the finger or the palm.

The storage circuit 46 temporarily stores therein signals calculated by the signal processing circuit 44. The storage circuit 46 may be, for example, a random-access memory (RAM) or a register circuit.

The coordinate extraction circuit 45 is a logic circuit that obtains detected coordinates of the asperities on the surface of the finger or the like when the contact or proximity of the finger is detected by the signal processing circuit 44. The coordinate extraction circuit 45 is the logic circuit that also obtains detected coordinates of blood vessels in the finger or the palm. The coordinate extraction circuit 45 combines the detection signals Vdet output from the photodiodes PD of the sensor 10 to generate two-dimensional information indicating the shape of the asperities on the surface of the finger or the like and two-dimensional information indicating the shape of the blood vessels in the finger or the palm. The coordinate extraction circuit 45 may output the detection signals Vdet as sensor output voltages Vo instead of calculating the detected coordinates.

The following describes a circuit configuration example of the detection device 1. FIG. 3 is a circuit diagram illustrating the detection device. As illustrated in FIG. 3, the sensor 10 has a plurality of partial detection areas PAA arranged in a matrix having a row-column configuration. Each of the partial detection areas PAA is provided with the photodiode PD.

The gate lines GCL extend in the first direction Dx, and are each coupled to the partial detection areas PAA arranged in the first direction Dx. A plurality of gate lines GCL(1), GCL(2), . . . , GCL(8) are arranged in the second direction Dy, and are each coupled to the gate line drive circuit 15. In the following description, the gate lines GCL(1), GCL(2), . . . , GCL(8) will each be simply referred to as the gate line GCL when need not be distinguished from one another. To facilitate understanding of the description, FIG. 3 illustrates eight gate lines GCL. However, this is merely an example, and M gate lines GCL may be arranged (where M is 8 or larger, and is, for example, 256).

The signal lines SGL extend in the second direction Dy and are each coupled to the photodiodes PD in the partial detection areas PAA arranged in the second direction Dy. A plurality of signal lines SGL(1), SGL(2), . . . , SGL(12) are arranged in the first direction Dx and are each coupled to the signal line selection circuit 16 and a reset circuit 17. In the following description, the signal lines SGL(1), SGL(2), . . . , SGL(12) will each be simply referred to as the signal line SGL when need not be distinguished from one another.

To facilitate understanding of the description, 12 signal lines SGL are illustrated. However, this is merely an example, and N signal lines SGL may be arranged (where N is 12 or larger, and is, for example, 252). The resolution of the sensor is, for example, 508 dots per inch (dpi), and the number of cells is 252×256. In FIG. 3, the sensor 10 is provided between the signal line selection circuit 16 and the reset circuit 17. The present disclosure is not limited thereto. The signal line selection circuit 16 and the reset circuit 17 may be coupled to ends of the signal lines SGL in the same direction.

The gate line drive circuit 15 receives various control signals including, for example, the start signal STV, the clock signal CK, and a reset signal RST1 from the control circuit 122 (refer to FIG. 1). The gate line drive circuit 15 sequentially selects the gate lines GCL(1), GCL(2), . . . , GCL(8) in a time-division manner based on the various control signals. The gate line drive circuit 15 supplies the gate drive signal VGL to the selected one of the gate lines GCL. This operation supplies the gate drive signal VGL to a plurality of drive transistors Tr coupled to the gate line GCL, and corresponding ones of the partial detection areas PAA arranged in the first direction Dx are selected as detection targets.

The signal line selection circuit 16 includes a plurality of selection signal lines Lsel, a plurality of output signal lines Lout, and output transistors TrS. The output transistors TrS are provided correspondingly to the respective signal lines SGL. Six signal lines SGL(1), SGL(2), . . . , SGL(6) are coupled to a common output signal line Lout1. Six signal lines SGL(7), SGL(8), . . . , SGL(12) are coupled to a common output signal line Lout2. The output signal lines Lout1 and Lout2 are each coupled to the detection circuit 48.

The signal lines SGL(1), SGL(2), . . . , SGL(6) are grouped into a first signal line block, and the signal lines SGL(7), SGL(8), . . . , SGL(12) are grouped into a second signal line block. The selection signal lines Lsel are coupled to the gates of the respective output transistors Trs included in one of the signal line blocks. One of the selection signal lines Lsel is coupled to the gates of the output transistors TrS in the signal line blocks.

The control circuit 122 (refer to FIG. 1) sequentially supplies the selection signal ASW to the selection signal lines Lsel. This operation causes the signal line selection circuit 16 to operate the output transistors Trs to sequentially select the signal lines SGL in one of the signal line blocks in a time-division manner. The signal line selection circuit 16 selects one of the signal lines SGL in each of the signal line blocks. With the above-described configuration, the detection device 1 can reduce the number of integrated circuits (ICs) including the detection circuit 48 or the number of terminals of the ICs. The signal line selection circuit 16 may couple more than one of the signal lines SGL collectively to the detection circuit 48.

As illustrated in FIG. 3, the reset circuit 17 includes a reference signal line Lvr, a reset signal line Lrst, and reset transistors TrR. The reset transistors TrR are provided correspondingly to the signal lines SGL. The reference signal line Lvr is coupled to either the sources or the drains of the reset transistors TrR. The reset signal line Lrst is coupled to the gates of the reset transistors TrR.

The control circuit 122 supplies a reset signal RST2 to the reset signal line Lrst. This operation turns on the reset transistors TrR to electrically couple the signal lines SGL to the reference signal line Lvr. The power supply circuit 123 supplies a reference signal COM to the reference signal line Lvr. This operation supplies the reference signal COM to a capacitive element Ca (refer to FIG. 4) included in each of the partial detection areas PAA.

FIG. 4 is a circuit diagram illustrating the partial detection areas. FIG. 4 also illustrates a circuit configuration of the detection circuit 48. As illustrated in FIG. 4, the partial detection area PAA includes the photodiode PD, the capacitive element Ca, and a corresponding one of the drive transistors Tr. The capacitive element Ca is capacitance (sensor capacitance) generated in the photodiode PD and is equivalently coupled in parallel to the photodiode PD.

FIG. 4 illustrates two gate lines GCL(m) and GCL(m+1) arranged in the second direction Dy among the gate lines GCL. FIG. 4 also illustrates two signal lines SGL(n) and SGL(n+1) arranged in the first direction Dx among the signal lines SGL. The partial detection area PAA is an area surrounded by the gate lines GCL and the signal lines SGL.

The drive transistors Tr are provided correspondingly to the photodiodes PD. The drive transistor Tr is formed of a thin-film transistor, and in this example, formed of an n-channel metal oxide semiconductor (MOS) thin-film transistor (TFT).

The gates of the drive transistors Tr belonging to the partial detection areas PAA arranged in the first direction Dx are coupled to the gate line GCL. The sources of the drive transistors Tr belonging to the plurality of partial detection areas PAA aligned in the second direction Dy are coupled to the signal line SGL. The drain of the drive transistor Tr is coupled to the anode of the photodiode PD and the capacitive element Ca.

The cathode of the photodiode PD is supplied with the sensor power supply signal VDDSNS from the power supply circuit 123. The signal line SGL and the capacitive element Ca are supplied with the reference signal COM serving as an initial potential of the signal line SGL and the capacitive element Ca from the power supply circuit 123.

When the partial detection area PAA is irradiated with light in an exposure period Pex (refer to FIG. 7), a current corresponding to the amount of the light flows through the photodiode PD. As a result, an electric charge is stored in the capacitive element Ca. When the drive transistor Tr is turned on in a read period Pdet (refer to FIG. 7), a current corresponding to the electric charge stored in the capacitive element Ca flows through the signal line SGL. The signal line SGL is coupled to the detection circuit 48 through a corresponding one of the output transistors TrS of the signal line selection circuit 16. Thus, the detection device 1 can detect a signal corresponding to the amount of the light received by the photodiode PD in each of the partial detection areas PAA.

During the read period Pdet (refer to FIG. 7), a switch SSW of the detection circuit 48 is turned on to couple the detection circuit 48 to the signal line SGL. The detection signal amplifying circuit 42 of the detection circuit 48 converts a current supplied from the signal line SGL into a voltage corresponding to the value of the current, and amplifies the result. A reference potential (Vref) having a fixed potential is supplied to a non-inverting input portion (+) of the detection signal amplifying circuit 42, and the signal line SGL is coupled to an inverting input portion (−) of the detection signal amplifying circuit 42. In the embodiment, the same signal as the reference signal COM is supplied as the reference potential (Vref) voltage. The signal processing circuit 44 (refer to FIG. 2) calculates the difference between the detection signal Vdet when light is emitted and the detection signal Vdet when light is not emitted as each of the sensor output voltages Vo. The detection signal amplifying circuit 42 includes a capacitive element Cb and a reset switch RSW. During the reset period, the reset switch RSW is turned on to reset the electric charge of the capacitive element Cb.

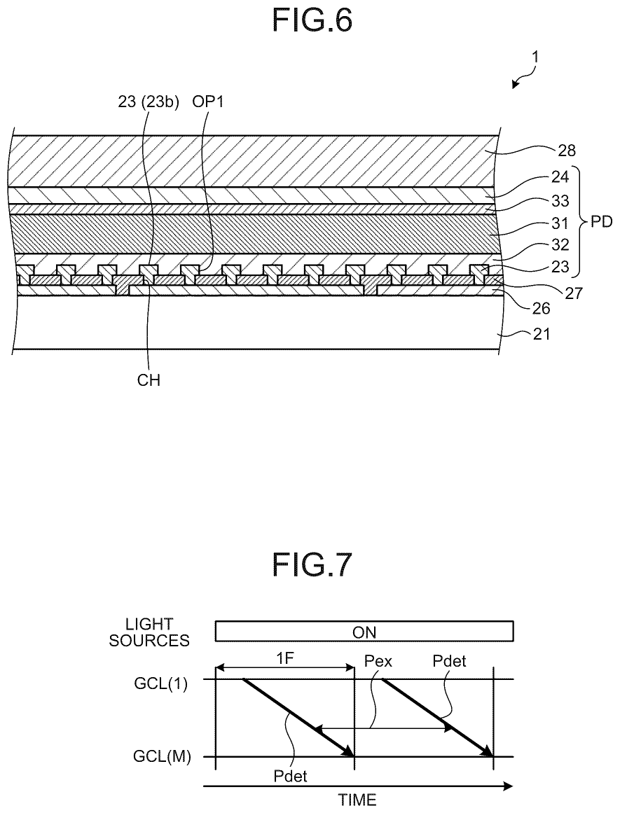

The following describes a configuration example of the photodiode PD. FIG. 5 is a plan view illustrating the lower electrodes of the detection device according to the embodiment in an enlarged manner. FIG. 5 illustrates the lower electrodes 23 with diagonal lines in order to facilitate viewing of the drawing. FIG. 5 mainly illustrates a configuration of the lower electrode 23 without illustrating, for example, the upper electrode 24, an active layer 31, a lower buffer layer 32, and an upper buffer layer 33 of the photodiode PD (refer to FIG. 6).

As illustrated in FIG. 5, the lower electrodes 23 are provided in a matrix having a row-column configuration on the substrate 21 so as to correspond to the respective photodiodes PD. The lower electrodes 23 are anode electrodes of the photodiodes PD and may be referred to as detection electrodes.

The outer shape of the lower electrode 23 is formed in a quadrilateral shape. The lower electrodes 23 each have a plurality of openings OP1. The openings OP1 are arranged in the first direction Dx and are each formed in a slit shape extending in the second direction Dy. In other words, the lower electrodes 23 each include a plurality of first electrode portions 23a and a plurality of second electrode portions 23b. The first electrode portions 23a and the second electrode portions 23b are each formed in a narrow linear shape.

The second electrode portions 23b are arranged in the first direction Dx and each extend in the second direction Dy. The two first electrode portions 23a each extend in the first direction Dx. One of the first electrode portions 23a is coupled to one end side in the second direction Dy of each of the second electrode portions 23b. The other of the first electrode portions 23a is coupled to the other end side in the second direction Dy of each of the second electrode portions 23b. In other words, the second electrode portions 23b are arranged between the two first electrode portions 23a in the second direction Dy. This configuration forms each of the openings OP1 in an area surrounded by the two first electrode portions 23a and two of the second electrode portions 23b.

The lower electrodes 23 are electrically coupled to power supply wiring lines 26 provided on the substrate 21 through contact holes CH formed in an insulating film 27 (refer to FIG. 6). More specifically, a plurality of the contact holes CH are provided in areas overlapping the respective second electrode portions 23b. The power supply wiring line 26 extends in the first direction Dx while intersecting the second electrode portions 23b, and is electrically coupled to the lower electrodes 23 through a plurality of contacts (contact holes CH). The power supply wiring line 26 is electrically coupled to the drive transistor Tr (refer to FIG. 4) provided on the substrate 21.

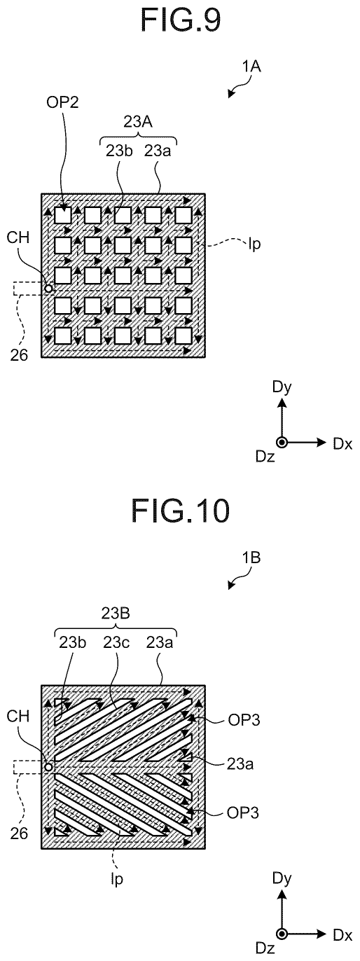

In the present embodiment, since a plurality of the contact holes CH are provided, the coupling resistance between the power supply wiring line 26 and the lower electrode 23 can be reduced compared with a configuration in which a contact formed at one point is provided for one lower electrode 23. Therefore, the actual resistance value can be reduced when supplying power to the lower electrode 23 through the power supply wiring line 26. The contact holes CH are located substantially in the center in the second direction Dy of each of the second electrode portions 23b of the lower electrode 23. Therefore, the length of current paths Ip (refer to FIGS. 9 and 10) when supplying power from the contact holes CH to one of the first electrode portions 23a can be made equal to the length of the current paths Ip when supplying power from the contact holes CH to the other of the first electrode portions 23a. However, the contact holes CH may be located off-center of the second electrode portions 23b.

The configuration of the lower electrode 23 illustrated in FIG. 5 is merely exemplary and can be changed as appropriate. The number of the second electrode portions 23b included in the lower electrode 23 is six, but is not limited to six, and may be from three to five, or seven or more. The width in the first direction Dx of the opening OP1 is substantially the same as the width in the first direction Dx of each of the second electrode portions 23b, but may differ from the width of the second electrode portion 23b.

The following describes a multilayer configuration of the photodiode PD. FIG. 6 is a sectional view along VI-VI′ of FIG. 5. FIG. 6 does not illustrate various transistors and various types of wiring (gate lines GCL, signal lines SGL, and so forth) formed on the substrate 21.

A direction from the substrate 21 toward a sealing film 28 in a direction orthogonal to a surface of the substrate 21 is referred to as “upper side” or simply “above”. A direction from the sealing film 28 toward the substrate 21 is referred to as “lower side” or simply “below”.

The substrate 21 is an insulating substrate and is made using, for example, glass or a resin material. The substrate 21 is not limited to having a flat plate shape and may have a curved surface. In this case, the substrate 21 may be made of a film-like resin.

The substrate 21 is provided with TFTs such as the drive transistor Tr and various types of wiring such as the gate lines GCL and the signal lines SGL. The substrate 21 on which the TFTs and the various types of wiring are formed is a drive circuit board for driving the sensor for each predetermined detection area, and is also called a backplane or an array substrate.

The power supply wiring lines 26 are provided on the substrate 21. The power supply wiring line 26 is, for example, metal wiring and is formed of a material having better conductivity than the lower electrode 23 of the photodiode PD. The power supply wiring line 26 is provided for each of the photodiodes PD (lower electrodes 23), and each power supply wiring line 26 is electrically coupled to the drive transistor Tr. The insulating film 27 is provided on the substrate 21 so as to cover the power supply wiring lines 26. The insulating film 27 may be an inorganic insulating film or an organic insulating film.

The photodiode PD is provided on the insulating film 27. In more detail, the photodiode PD includes the lower electrode 23, the lower buffer layer 32, the active layer 31, the upper buffer layer 33, and the upper electrode 24. In the photodiode PD, the lower electrode 23, the lower buffer layer 32 (hole transport layer), the active layer 31, the upper buffer layer 33 (electron transport layer), and the upper electrode 24 are stacked in this order in the direction orthogonal to the substrate 21.

The lower electrode 23 is an anode electrode of the photodiode PD and is formed of, for example, a light-transmitting conductive material such as indium tin oxide (ITO). The detection device 1 of the present embodiment is formed as a bottom-surface light receiving optical sensor in which the light from the object to be detected passes through the substrate 21 and enters the photodiode PD.

The active layer 31 changes in characteristics (for example, voltage-current characteristics and resistance value) according to light emitted thereto. An organic material is used as a material of the active layer 31. Specifically, the active layer 31 has a bulk heterostructure containing a mixture of a p-type organic semiconductor and an n-type fullerene derivative (PCBM) that is an n-type organic semiconductor. As the active layer 31, low-molecular-weight organic materials can be used including, for example, fullerene (C₆₀), phenyl-C₆₁-butyric acid methyl ester (PCBM), copper phthalocyanine (CuPc), fluorinated copper phthalocyanine (F₁₆CuPc), 5,6,11,12-tetraphenyltetracene (rubrene), and perylene diimide (PDI) (derivative of perylene).

The active layer 31 can be formed by a vapor deposition process (dry process) using any of the low-molecular-weight organic materials listed above. In this case, the active layer 31 may be, for example, a multilayered film of CuPc and F₁₆CuPc, or a multilayered film of rubrene and C₆₀. The active layer 31 can also be formed by a coating process (wet process). In this case, the active layer 31 is made using a material obtained by combining any of the above-listed low-molecular-weight organic materials with a high-molecular-weight organic material. As the high-molecular-weight organic material, for example, poly(3-hexylthiophene) (P3HT) and F8-alt-benzothiadiazole (F8BT) can be used. The active layer 31 can be a film made of a mixture of P3HT and PCBM, or a film made of a mixture of F8BT and PDI.

The lower buffer layer 32 is a hole transport layer and the upper buffer layer 33 is an electron transport layer. The lower buffer layer 32 and the upper buffer layer 33 are provided to facilitate holes and electrons generated in the active layer 31 to reach the lower electrode 23 or the upper electrode 24. The lower buffer layer 32 (hole transport layer) is in direct contact with the top of the lower electrode 23 and is also provided in the openings OP1. The active layer 31 is in direct contact with the top of the lower buffer layer 32. The material of the hole transport layer is a metal oxide layer. For example, tungsten oxide (WO₃) or molybdenum oxide is used as the oxide metal layer.

The upper buffer layer 33 (electron transport layer) is in direct contact with the top of the active layer 31, and the upper electrode 24 is in direct contact with the top of the upper buffer layer 33. Polyethylenimine ethoxylated (PEIE) is used as a material of the electron transport layer.

The materials and the manufacturing methods of the lower buffer layer 32, the active layer 31, and the upper buffer layer 33 are merely exemplary, and other materials and manufacturing methods may be used. For example, each of the lower buffer layer 32 and the upper buffer layer 33 is not limited to a single-layer film, but may be formed as a multilayered film that includes an electron block layer and a hole block layer.

The upper electrode 24 is provided on the upper buffer layer 33. The upper electrode 24 is a cathode electrode of the photodiode PD and is continuously formed over the entire detection area AA. In other words, the upper electrode 24 is continuously provided as the top layer of the photodiodes PD. The upper electrode 24 faces the lower electrodes 23 with the lower buffer layer 32, the active layer 31, and the upper buffer layer 33 interposed therebetween. The upper electrode 24 is formed of, for example, a light-transmitting conductive material such as ITO or indium zinc oxide (IZO).

The sealing film 28 is provided on the upper electrode 24. An inorganic insulating film such as a silicon nitride film or an aluminum oxide film or a resin film such as an acrylic film is used as the sealing film 28. The sealing film 28 is not limited to a single layer, and may be a multilayered film having two or more layers obtained by combining the inorganic film with the resin film mentioned above. The sealing film 28 well seals the photodiode PD, and thus can reduce water entering the photodiode PD from the upper surface side thereof.

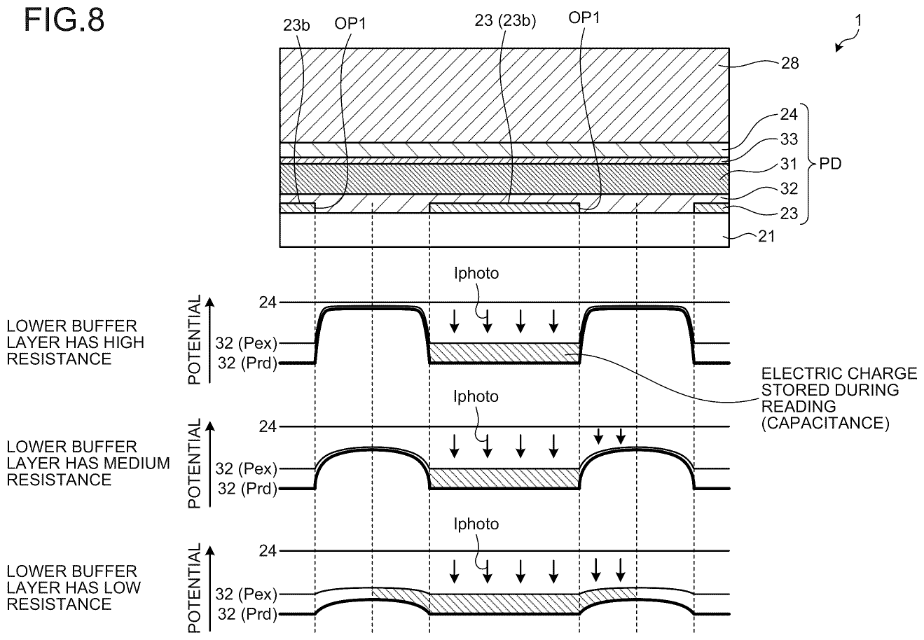

The following describes an operation example of the detection device 1 during the exposure period Pex and the read period Pdet with reference to FIGS. 7 and 8. FIG. 7 is an explanatory diagram for explaining the operation example of the detection device. As illustrated in FIG. 7, the exposure period Pex and the read period Pdet are alternately provided. During the exposure period Pex, the drive transistor Tr is caused to be off and the active layer 31 of the photodiode PD is charged with photocarriers (electrons or holes) according to the light received by the photodiode PD. During the read period Pdet, the gate line drive circuit 15 (refer to FIG. 2) sequentially scans the gate lines GCL(1) to GCL(M), and thus, the drive transistors Tr in the each row are driven. Through this operation, the photodiodes PD in the each row are read during the read period Pdet.

As described above, in the present embodiment, the openings OP1 are provided in the lower electrode 23. Therefore, compared with a case where the lower electrode 23 is formed of a continuous solid film, the capacitance between the lower electrode 23 and the upper electrode 24 facing each other can be reduced, and thus the time constant of the lower electrode 23 can be reduced. As a result, the time required for the read period Pdet can be reduced, and the time required for detection of one frame (1F) can be reduced. The detection of one frame (1F) refers to that the photodiodes PD in the entire detection area AA are detected. In the example illustrated in FIG. 7, the detection of one frame (1F) refers to detection after the completion of reading of the gate lines GCL(M) in the last row until the completion of reading of the photodiodes PD in the respective rows from the gate lines GCL(1) to the gate line GCL(M).

FIG. 8 illustrates explanatory diagrams each for explaining the potential of the lower buffer layer in areas overlapping the electrode portion and the opening of the lower electrode. FIG. 8 illustrates a portion of the lower electrode 23 in an enlarged manner and illustrates one of the second electrode portions 23b and the openings OP1 adjacent to the second electrode portion 23b. In FIG. 8, the sign “32 (Pex)” indicates the potential after the exposure period Pex of the lower buffer layer 32, and the sign “32 (Prd)” indicates the potential after the read period Pdet of the lower buffer layer 32. These potentials of the lower buffer layer 32 are illustrated for each sheet resistance (high resistance, medium resistance, and low resistance) of the lower buffer layer 32. FIG. 8 illustrates the change in potential of the lower buffer layer 32 assuming that the potential of the upper electrode 24 is constant.

In FIG. 8, the expression that the lower buffer layer 32 has high resistance refers to a case where the sheet resistance of the lower buffer layer 32 has a larger value than 1×10¹³ Ω/sq. The expression that the lower buffer layer 32 has medium resistance refers to a case where the sheet resistance of the lower buffer layer 32 has a value that is equal to or larger than 1×10¹⁰ Ω/sq. but not larger than 1×10¹³ Ω/sq. The expression that the lower buffer layer 32 has low resistance refers to a case where the sheet resistance of the lower buffer layer 32 has a smaller value than 1×10¹⁰ Ω/sq.

As illustrated in FIG. 8, when the lower buffer layer 32 has high resistance, photocarriers (electrons or holes) in the lower buffer layer 32 in an area overlapping the opening OP1 hardly flow to the lower electrode 23 (second electrode portion 23b) during the read period Pdet. During also the exposure period Pex, the photocarriers generated in the area overlapping the opening OP1 cannot be transported to the lower electrode 23 (second electrode portion 23b). As a result, the potential of the lower buffer layer 32 in the area overlapping the opening OP1 increases; no electric field is applied to the active layer 31 in the area overlapping the opening OP1; and a current Iphoto does not flow in that area.

Thus, when the lower buffer layer 32 has high resistance, the time constant can be reduced by providing a plurality of the openings OP1 in the lower electrode 23, but the detection in the active layer 31 in the areas overlapping the openings OP1 is restrained, and therefore the detection sensitivity may be reduced.

When the lower buffer layer 32 has medium resistance, the photocarriers (electrons or holes) in the lower buffer layer 32 in the area overlapping the opening OP1 hardly flow to the lower electrode 23 (second electrode portion 23b) during the read period Pdet. However, unlike in the above-described case where the lower buffer layer 32 has high resistance, in the exposure period Pex, photocarriers generated in the area overlapping the opening OP1 can be transported to the lower electrode 23 (second electrode portion 23b). As a result, the increase in potential of the lower buffer layer 32 in the area overlapping the opening OP1 is limited to a certain level; the electric field is also applied to the active layer 31 in the area overlapping the opening OP1; and the current Iphoto in this area also flows.

Thus, when the lower buffer layer 32 has medium resistance, the time constant of the lower electrode 23 can be reduced by providing the openings OP1 in the lower electrode 23, and the detection is enabled also in the active layer 31 in the areas overlapping the openings OP1. Thus, the decrease in the detection sensitivity can be suppressed. The sheet resistance of the lower buffer layer 32 of the present embodiment is a medium resistance within a range from 1×10¹⁰ to 1×10¹³ Ω/sq., and is approximately 3.3×10¹¹ Ω/sq., for example.

When the lower buffer layer 32 has low resistance, unlike in the case where the lower buffer layer 32 has high or medium resistance, most of the photocarriers (electrons or holes) in the lower buffer layer 32 in the area overlapping the opening OP1 flow to the lower electrode 23 (second electrode portion 23b) during the read period Pdet.

Therefore, when the lower buffer layer 32 has low resistance, providing the openings OP1 in the lower electrode 23 can also suppress the decrease in detection sensitivity. However, since the potential of the lower buffer layer 32 in the areas overlapping the openings OP1 is low during the reading, the apparent capacitance between the lower electrode 23 and the upper electrode 24 does not decrease, and thereby the time constant may be difficult to decrease.

As described above, when the lower buffer layer 32 has medium resistance, providing the openings OP1 in the lower electrode 23 has the effects of reducing the time constant of the lower electrode 23 and suppressing the decrease in the detection sensitivity. When the lower buffer layer 32 has low or high resistance, the number and area of the openings OP1 can be appropriately set according to characteristics (time constant, detection sensitivity, and so forth) required for the detection device 1.

### First Modification

FIG. 9 is a plan view illustrating a lower electrode of a detection device according to a first modification in an enlarged manner. As illustrated in FIG. 9, in a detection device 1A according to the first modification, a plurality of openings OP2 of a lower electrode 23A are each formed in a quadrilateral shape and are arranged in a matrix having a row-column configuration.

In other words, the first electrode portions 23a extending in the first direction Dx and the second electrode portions 23b extending in the second direction Dy of the lower electrodes 23A are arranged in a grid pattern so as to intersect each other. The openings OP2 are each formed in an area surrounded by two of the first electrode portions 23a and two of the second electrode portions 23b. The number, area, arrangement pattern, and so forth of the openings OP2 can be changed according to the time constant, the detection sensitivity, and so forth required for the detection device 1.

In the first modification, the lower electrode 23A is electrically coupled to the power supply wiring line 26 through the contact hole CH at one point. Although the coupling resistance between the power supply wiring line 26 and the lower electrode 23A is larger than in the embodiment described above, asperities caused by the contact holes CH are reduced and the flatness of the lower buffer layer 32, the active layer 31, and the upper buffer layer 33 of the photodiode PD can be improved.

### Second Modification

FIG. 10 is a plan view illustrating a lower electrode of a detection device according to a second modification in an enlarged manner. As illustrated in FIG. 10, in a detection device 1B according to the second modification, a plurality of openings OP3 of a lower electrode 23B are each formed in a slit shape and extend at a predetermined angle with respect to the arrangement direction of the photodiodes PD (for example, the first direction Dx). The openings OP3 are arranged to be line-symmetric with respect to an imaginary line extending in the first direction Dx through the contact hole CH. The openings OP3 radially extend from the contact hole CH that is a contact between the power supply wiring line 26 and the lower electrode 23B.

In other words, the lower electrodes 23B include the first electrode portions 23a extending in the first direction Dx, the second electrode portions 23b extending in the second direction Dy, and a plurality of third electrode portions 23c extending at a predetermined angle with respect to the first and the second electrode portions 23a and 23b. The third electrode portions 23c are arranged in a rectangular area surrounded by two of the first electrode portions 23a and two of the second electrode portions 23b. Three of the first electrode portions 23a are arranged in the second direction Dy, and the third electrode portions 23c are arranged to be line-symmetric with respect to the first electrode portion 23a located in the center in the second direction Dy of the photodiode PD.

Compared with the first modification described above, the present modification can shorten the current paths Ip when supplying power from a contact with the power supply wiring line 26 of the lower electrode 23B (contact hole CH) to a position away from the contact hole CH, such as the upper right corner of the lower electrode 23B. That is, in the present modification, even when the number of the contact holes CH provided in the lower electrode 23B is small, the resistance to the power supply to the lower electrode 23B can be reduced.

In the first embodiment, the first modification, and the second modification described above, each of the lower electrodes 23, 23A, and 23B is the anode electrode of the photodiode PD, and the upper electrode 24 is the cathode electrode of the photodiode PD. However, the present disclosure is not limited to this configuration. Each of the lower electrode 23, 23A, and 23B may be the cathode electrode of the photodiode PD, and the upper electrode 24 may be the anode electrode of the photodiode PD. In that case, in the photodiode PD, the lower buffer layer 32 is configured with an electron transport layer, and the upper buffer layer 33 is configured with a hole transport layer.

The lower electrodes 23, 23A, and 23B all have a quadrilateral outer shape, but the shape is not limited thereto. The lower electrodes 23, 23A, and 23B can have other shapes such as a polygonal shape and a circular shape.

While the preferred embodiment of the present disclosure has been described above, the present disclosure is not limited to the embodiment described above. The content disclosed in the embodiment is merely an example, and can be variously modified within the scope not departing from the gist of the present disclosure. Any modifications appropriately made within the scope not departing from the gist of the present disclosure also naturally belong to the technical scope of the present disclosure. At least one of various omissions, substitutions, and changes of the components can be made without departing from the gist of the embodiment and the modifications described above.

What is claimed is:

1. A detection device comprising:
a substrate; and
a plurality of photodiodes arranged on the substrate, wherein
each of the photodiodes includes a lower electrode, a lower buffer layer, an active layer, an upper buffer layer, and an upper electrode that are stacked on the substrate in the order as listed, and
a plurality of the lower electrodes are each provided with a plurality of openings.

2. The detection device according to claim 1, wherein
the lower buffer layer includes either a hole transport layer or an electron transport layer, and
the upper buffer layer includes the other of the hole transport layer and the electron transport layer.

3. The detection device according to claim 1, wherein the lower buffer layer has sheet resistance of equal to or larger than 1×10¹⁰ Ω/sq. and not larger than 1×10¹³ Ω/sq.

4. The detection device according to claim 1, wherein the openings of the lower electrode are arranged in a first direction and are each formed in a slit shape extending in a second direction intersecting the first direction.

5. The detection device according to claim 1, wherein the openings of the lower electrode are arranged in a matrix having a row-column configuration.

6. The detection device according to claim 1, wherein the openings of the lower electrode are each formed in a slit shape and extend at a predetermined angle with respect to an arrangement direction of the photodiodes.

7. The detection device according to claim 6, comprising power supply wiring line coupled to the lower electrode, wherein
the openings radially extend from a contact between the power supply wiring line and the lower electrode.
